(19) United States
(12) Patent Application Publication
(10) Pub. No.: US 2024/0145301 A1
(43) Pub. Date: May 2, 2024

(54) METAL THIN-FILM PRECURSOR COMPOSITION, METHOD OF FORMING THIN FILM USING METAL THIN-FILM PRECURSOR COMPOSITION, AND SEMICONDUCTOR SUBSTRATE FABRICATED USING METHOD

(71) Applicant: SOULBRAIN CO., LTD., Gyeonggi-do (KR)

(72) Inventors: Chang Bong YEON, Gyeonggi-do (KR); Jae Sun JUNG, Gyeonggi-do (KR); Ji Hyun NAM, Gyeonggi-do (KR)

(21) Appl. No.: 18/277,075

(22) PCT Filed: Mar. 4, 2022
(86) PCT No.: PCT/KR2022/003064

§ 371 Date: Sep. 15, 2023

(30) Foreign Application Priority Data
Mar. 4, 2021 (KR) 10-2021-0028835
Mar. 4, 2022 (KR) 10-2022-0027866

(51) Int. Cl. H01L 21/768; C23C 16/34; C23C 16/44; C23C 16/448; C23C 16/455; C23C 16/46; C23C 16/50; H01L 21/285

(52) U.S. Cl. CPC H01L 21/76841; C23C 16/34; C23C 16/4408; C23C 16/448; C23C 16/45534; C23C 16/45553; C23C 16/46; C23C 16/50; H01L 21/28556

(57) ABSTRACT

Disclosed are a metal thin film precursor composition, a method of forming a thin film using the metal thin film precursor composition, and a semiconductor substrate fabricated using the method. The metal thin film precursor composition includes a metal thin film precursor compound and a growth regulator including a predetermined terminal group and structure. In a thin film deposition process, by using the metal thin film precursor composition, side reactions may be suppressed and thin film growth rate may be controlled appropriately. Since process by-products in a thin film are removed, even when the thin film is formed on a substrate having a complicated structure, step coverage and the thickness uniformity and resistivity characteristics of the thin film may be greatly improved. In addition, corrosion or deterioration may be prevented, and the crystallinity of the thin film may be improved, thereby improving the electrical properties of the thin film.

### TECHNICAL FIELD

The present invention relates to a metal thin film precursor composition, a method of forming a thin film using the metal thin film precursor composition, and a semiconductor substrate fabricated using the method. More particularly, the present invention relates to a metal thin film precursor composition that is capable of inhibiting side reactions to reduce the concentration of impurities in a thin film, is capable of preventing corrosion or deterioration of a thin film to improve the electrical properties of the thin film, is capable of appropriately controlling the growth rate of a thin film to improve step coverage and the thickness uniformity and resistivity of the thin film even when the thin film is formed on a substrate having a complicated structure, and does not decompose even when mixed with a thin film precursor, a method of forming a thin film using the metal thin film precursor composition, and a semiconductor substrate fabricated using the method.

### BACKGROUND ART

Development of high-integration memory and non-memory semiconductor devices is actively progressing. As the structures of memory and non-memory semiconductor devices become increasingly complex, the importance of thin film quality and step coverage is gradually increasing when depositing various thin films on substrates.

A thin film for semiconductors is made of a metal nitride, silicon nitride, a metal oxide, silicon oxide, or the like. Examples of the metal nitride or silicon nitride include titanium nitride (TiN), tantalum nitride (TaN), zirconium nitride (ZrN), AIN, TiSiN, TiAIN, TiBN, TION, TiCN, SiN, and the like. The thin film is generally used as a diffusion barrier between the silicon layer of a doped semiconductor and aluminum (Al) or copper (Cu) used as an interlayer wiring material. However, when depositing a tungsten (W) or molybdenum (Mo) metal thin film on a substrate, the thin film serves as an adhesion layer. Various metal oxide thin films or silicon oxide thin films made of SiO₂, ZrO₂, HfO₂, or TiO₂ are being developed. The metal thin film may be made of Ti, Mo, W, or Co, and the thin film is commonly used for dielectric, insulating, and wiring purposes.

To impart excellent and uniform physical properties to a thin film deposited on a substrate, the formed thin film must have high step coverage. Accordingly, the atomic layer deposition (ALD) process using a surface reaction is used rather than the chemical vapor deposition (CVD) process using a gas phase reaction, but there are still problems to be solved to realize 100% step coverage.

In addition, to improve step coverage, a method of reducing the growth rate of a thin film has been proposed. However, when decreasing deposition temperature to reduce the growth rate of a thin film, impurities such as carbon and chlorine remaining in the thin film increase, and film quality deteriorates.

In addition, in the case of titanium tetrachloride (TiCl₄) used to deposit titanium nitride (TiN), which is a typical metal nitride, process by-products such as chlorides remain in a formed thin film, causing corrosion of metals such as aluminum. In addition, film quality deteriorates due to generation of non-volatile by-products.

Therefore, it is necessary to develop a method of forming a thin film having a complex structure that contains a small amount of residual impurities and does not cause corrosion of interlayer wiring materials and a semiconductor substrate fabricated using the method. In addition, it is necessary to develop a growth regulator that is capable of providing uniform thickness and step coverage even at a high aspect ratio according to the number of VNAND stacks, which increase to 128 layers, 256 layers, 512 layers, or the like, and does not decompose even when mixed with a thin film precursor.

### RELATED ART DOCUMENTS

### Patent Documents

KR 2006-0037241 A

KR 2018-0057059 A

### DISCLOSURE

### Technical Problem

Therefore, the present invention has been made in view of the above problems, and it is one object of the present invention to provide a metal thin film precursor composition including a growth regulator that is capable of greatly improving the quality of a thin film including the auxiliary precursor by providing a low bandgap, is capable of appropriately controlling the growth rate of a thin film by inhibiting side reactions, is capable of preventing corrosion or deterioration by removing process by-products from a thin film, is capable of greatly improving step coverage and the thickness uniformity and resistivity characteristics of a thin film even when the thin film is formed on a substrate having a complicated structure, and does not decompose even when mixed with a thin film precursor; a method of forming a thin film using the metal thin film precursor composition; and a semiconductor substrate fabricated using the method.

It is another object of the present invention to improve the density and electrical properties (e.g., resistivity) of a thin film by improving the crystallinity of the thin film.

The above and other objects can be accomplished by the present invention described below.

### Technical Solution

In accordance with one aspect of the present invention, provided is a metal thin film precursor composition including a thin film precursor compound; and a growth regulator,

wherein the thin film precursor compound includes a compound represented by Chemical Formula 1 below, and

the growth regulator is a straight-chain, branched, cyclic, or aromatic compound represented by Chemical Formula 2 below.

MₓNₙLₘ, [Chemical Formula 1]

wherein x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; n is an integer from 0 to 8; N is F, Cl, Br, or I or a ligand consisting of a combination of two or more selected from the group consisting of F, Cl, Br, and I; m is an integer from 0 to 5; and L is H, C, N, O, P, or S or a ligand consisting of a combination of two or more selected from the group consisting of H, C, N, O, and P.

AnBmXoYiZj, [Chemical Formula 2]

wherein A is carbon, silicon, nitrogen, phosphorus, or sulfur; B is hydrogen, an alkyl having 1 to 10 carbon atoms, a cycloalkyl having 3 to 10 carbon atoms, or an alkoxy having 1 to 10 carbon atoms; X includes one or more of fluorine (F), chlorine (Cl), bromine (Br), and iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.

n may be an integer from 1 to 6.

N may be F, Cl, or Br or a ligand consisting of a combination of two or more selected from the group consisting of F, Cl, and Br.

The growth regulator may be Cl, Br, or I or a halide terminal group consisting of a combination of two or more selected from the group consisting of Cl, Br, and I.

The thin film precursor compound may include one or more selected from compounds represented by Chemical Formulas 3 to 39 below.

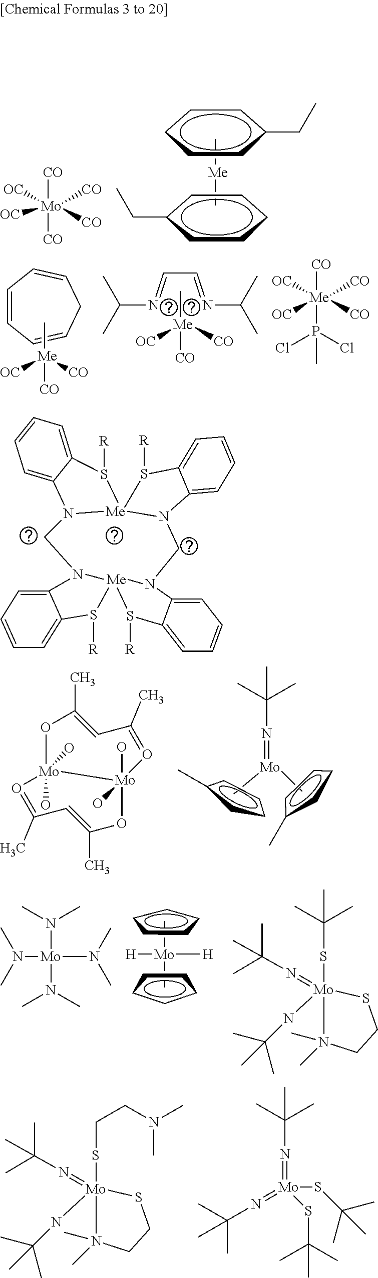

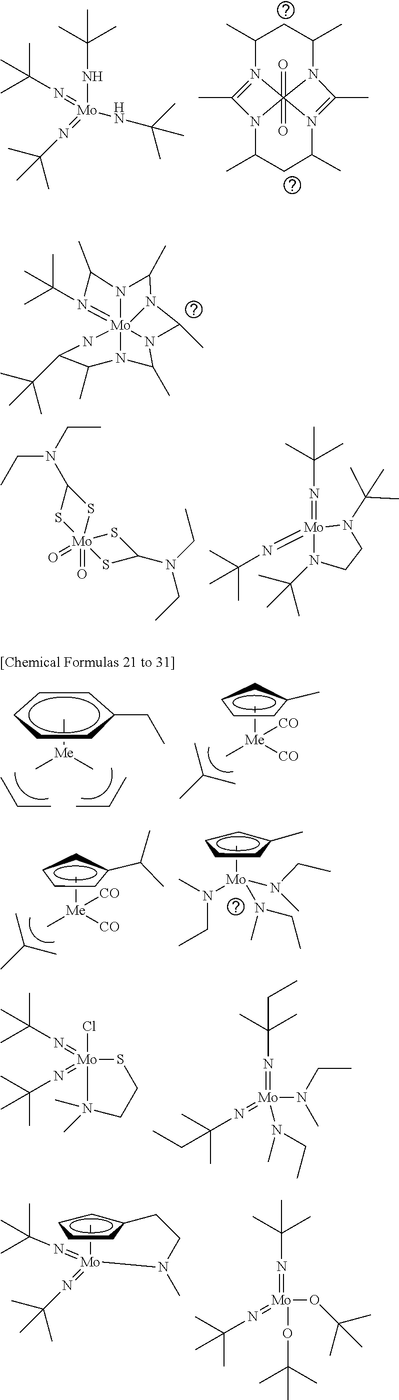

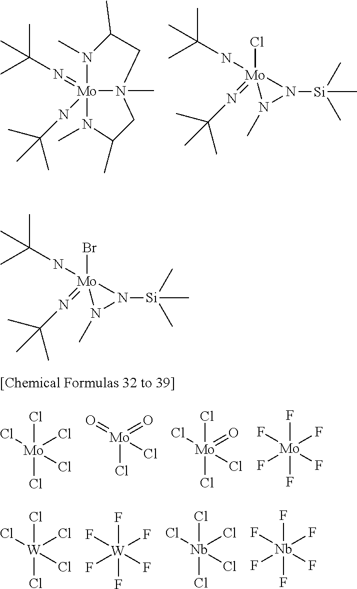

In Chemical Formulas 3 to 39, a line is a bond; carbon is located at a point where bonds meet without indicating a separate element; the number of hydrogen atoms satisfying a valence of the carbon is omitted; R′ and R″ are each hydrogen or an alkyl group having 1 to 5 carbon atoms; and R′ is connected to adjacent R′.

A weight ratio of the growth regulator to the thin film precursor compound may be 1:99 to 99:1.

The growth regulator may include one or more selected from compounds represented by Chemical Formulas 40 to 60 below.

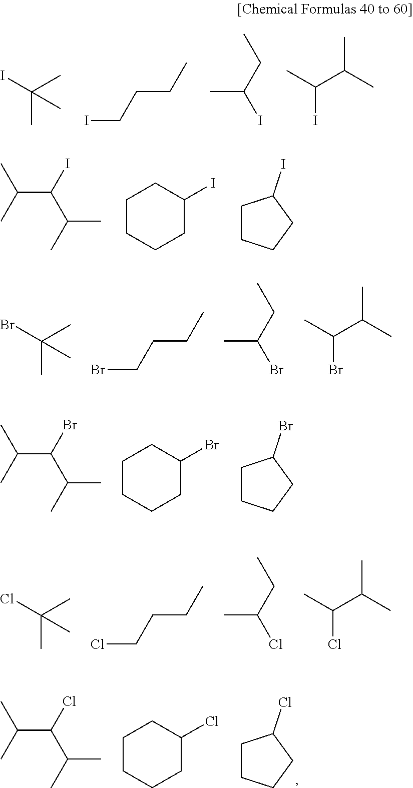

wherein, in Chemical Formulas 40 to 60, a line is a bond; carbon is located at a point where bonds meet without indicating a separate element; and the number of hydrogen atoms satisfying a valence of the carbon is omitted.

The metal thin film precursor composition may be used in an atomic layer deposition (ALD) process, a plasma atomic layer deposition (PEALD) process, a chemical vapor deposition (CVD) process, or a plasma chemical vapor deposition (PECVD) process.

In accordance with another aspect of the present invention, provided is a method of forming a thin film, the method including injecting the above-described metal thin film precursor composition into a chamber and adsorbing the metal thin film precursor composition on a surface of a loaded substrate.

In addition, the method of the present invention may include:
i) vaporizing a growth regulator and adsorbing the growth regulator on a surface of a substrate loaded in a chamber;
ii) performing first purging of an inside of the chamber using a purge gas;
iii) vaporizing a thin film precursor compound in the chamber and adsorbing the thin film precursor compound on a surface area different from the surface area of the substrate on which the growth regulator is adsorbed or bonding the thin film precursor compound to a terminal of the growth regulator adsorbed on the substrate;
iv) performing second purging of the inside of the chamber using a purge gas;
v) supplying a reaction gas into the chamber; and
vi) performing third purging of the inside of the chamber using a purge gas.

In addition, the method of the present invention may include:
i-1) vaporizing a thin film precursor compound and adsorbing the thin film precursor compound on a surface area of the substrate loaded in the chamber, wherein the surface area is different from the surface area of the substrate on which the growth regulator is adsorbed, or bonding the thin film precursor compound to a terminal of the growth regulator adsorbed on the substrate;
ii) performing first purging of an inside of the chamber using a purge gas;
v) supplying a reaction gas into the chamber; and
vi-1) performing additional purging of the inside of the chamber using a purge gas.

In addition, the method of the present invention may include:
i-2) vaporizing a thin film precursor compound and adsorbing the thin film precursor compound on a surface of a substrate loaded in a chamber;
ii) performing first purging of an inside of the chamber using a purge gas;
iii-1) vaporizing a growth regulator in the chamber and adsorbing the growth regulator on a surface area different from the surface area of the substrate on which the thin film precursor compound is adsorbed or bonding the growth regulator to a terminal of the thin film precursor compound adsorbed on the substrate;
iv) performing second purging of the inside of the chamber using a purge gas;
v) supplying a reaction gas into the chamber; and
vi) performing third purging of the inside of the chamber using a purge gas.

The metal thin film precursor composition may be transferred into an ALD chamber, a CVD chamber, a PEALD chamber, or a PECVD chamber by a VFC method, a DLI method, or an LDS method.

The growth regulator and the thin film precursor compound constituting the metal thin film precursor composition may be fed into the chamber at a feeding ratio (mg/cycle) of 1:0.1 to 1:20.

The reaction gas may be a reducing agent, a nitrifying agent, or an oxidizing agent.

In the method of forming a thin film, deposition temperature may be 50 to 700° C.

The thin film may be an oxide film, a nitride film, or a metal film.

The thin film may include a multilayer structure consisting of two or three layers.

In accordance with yet another aspect of the present invention, provided is a semiconductor substrate fabricated using the above-described method of forming a thin film.

The semiconductor substrate may be low-resistance metal gate interconnect, a high-aspect-ratio 3D metal-insulator-metal (MIM) capacitor, a DRAM trench capacitor, 3D gate-all-around (GAA), or 3D NAND.

### Advantageous Effects

According to the present invention, by appropriately controlling thin film growth rate by controlling deposition rate, even when a thin film is formed on a substrate having a complicated structure, a metal thin film precursor composition including a growth regulator capable of improving step coverage and film quality can be provided.

In addition, the present invention has an effect of providing a growth regulator for forming a thin film that is capable of controlling the adsorption structure and growth rate of a thin film precursor compound during thin film formation due to reaction stability to the thin film precursor compound, is capable of preventing corrosion or deterioration by reducing process by-products, and is capable of improving the resistivity characteristics and electrical properties of a thin film by improving the crystallinity of the thin film. In addition, the present invention has an effect of providing a method of forming a thin film using the growth regulator and a semiconductor substrate fabricated using the method.

### DESCRIPTION OF DRAWINGS

FIG. 1 shows the results of comparing an experiment in which MoO₂Cl₂ was injected first and the growth regulator of the present invention was injected later and a control experiment in which no growth regulator was used.

FIG. 2 shows the results of comparing an experiment in which the growth regulator of the present invention was injected first and NbF₅ was injected later and a control experiment in which no growth regulator was used. The left drawing shows the SIMS depth profile of a control NbN thin film, and the right drawing shows the SIMS depth profile of an NbN thin film formed by pre-injecting the growth regulator of the present invention.

### BEST MODE

Hereinafter, a growth regulator, a metal thin film precursor composition, a method of forming a thin film using the metal thin film precursor composition, and a semiconductor substrate fabricated using the method according to the present invention will be described in detail.

The present inventors confirmed that, when adsorbing a metal thin film precursor compound on the surface of a substrate loaded in a chamber, when adsorbing the metal thin film precursor compound in combination with a growth regulator having a predetermined terminal and structure, the adsorption structure and growth rate of the thin film precursor compound were adjusted, process by-products were reduced, corrosion or deterioration was prevented, the crystallinity of a thin film was improved, and as a result, the resistivity characteristics and electrical properties of the thin film were greatly improved. In addition, the present inventors confirmed that resistivity characteristics were greatly improved in all cases of adsorbing a composition including a metal thin film precursor compound and a specific growth regulator on the surface of a substrate loaded in a chamber; adsorbing the thin film precursor compound on the surface of a substrate loaded in a chamber and then adsorbing the growth regulator on the surface; and adsorbing the growth regulator on the surface of a substrate loaded in a chamber and then adsorbing the thin film precursor compound on the surface. Based on these results, the present inventors conducted further studies to complete the present invention.

As a preferred example, the method of forming a thin film may include step i) of vaporizing a growth regulator and adsorbing the growth regulator on the surface of a substrate loaded in a chamber; step ii) of performing first purging of the inside of the chamber using a purge gas; step iii) of vaporizing a thin film precursor compound in the chamber and adsorbing the thin film precursor compound on a surface area different from the surface area of the substrate on which the growth regulator is adsorbed or bonding the thin film precursor compound to a terminal of the growth regulator adsorbed on the substrate; step iv) of performing second purging of the inside of the chamber using a purge gas; step v) of supplying a reaction gas into the chamber; and step vi) of performing third purging of the inside of the chamber using a purge gas. In this case, thin film growth rate may be controlled. In addition, even when deposition temperature increases during thin film formation, process by-products may be effectively removed, thereby improving the resistivity of a thin film and step coverage.

As another preferred example, the method of forming a thin film may include step i-1) of vaporizing a thin film precursor compound and adsorbing the thin film precursor compound on a surface area of the substrate loaded in the chamber, wherein the surface area is different from the surface area of the substrate on which the growth regulator is adsorbed, or bonding the thin film precursor compound to a terminal of the growth regulator adsorbed on the substrate; step ii) of performing first purging of the inside of the chamber using a purge gas; step v) of supplying a reaction gas into the chamber; and step vi-1) of performing additional purging of the inside of the chamber using a purge gas. In this case, thin film growth rate may be controlled. In addition, even when deposition temperature increases during thin film formation, process by-products may be effectively removed, thereby improving the resistivity of a thin film and step coverage.

As another preferred example, the method of forming a thin film may include step i-2) of vaporizing a thin film precursor compound and adsorbing the thin film precursor compound on the surface of a substrate loaded in a chamber; step ii) of performing first purging of the inside of the chamber using a purge gas; step iii-1) of vaporizing a growth regulator in the chamber and adsorbing the growth regulator on a surface area different from the surface area of the substrate on which the thin film precursor compound is adsorbed or bonding the growth regulator to a terminal of the thin film precursor compound adsorbed on the substrate; step iv) of performing second purging of the inside of the chamber using a purge gas; step v) of supplying a reaction gas into the chamber; and vi) performing third purging of the inside of the chamber using a purge gas. In this case, thin film growth rate may be controlled. In addition, even when deposition temperature increases during thin film formation, process by-products may be effectively removed, thereby improving the resistivity of a thin film and step coverage.

The metal thin film precursor composition including the growth regulator and the metal thin film precursor compound may preferably be transferred to a chamber by a VFC method, a DLI method, or an LDS method, more preferably an LDS method.

The metal thin film precursor composition including the growth regulator and the metal thin film precursor compound may preferably be used in an atomic layer deposition (ALD) process, a plasma atomic layer deposition (PEALD) process, a chemical vapor deposition (CVD) process, or a plasma chemical vapor deposition (PECVD) process, more preferably an atomic layer deposition (ALD) process or a plasma chemical vapor deposition (PECVD) process.

The metal thin film precursor compound may include a compound represented by Chemical Formula 1 below.

MₓNₙLₘ [Chemical Formula 1]

In Chemical Formula 1, x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; n is an integer from 0 to 8; N is F, Cl, Br, or I or a ligand consisting of a combination of two or more selected from the group consisting of F, Cl, Br, and I; m is an integer from 0 to 5; and L is H, C, N, O, P, or S or a ligand consisting of a combination of two or more selected from the group consisting of H, C, N, O, and P. In this case, the desired effects of the present invention may be realized, and the resistivity of a thin film may be improved.

For example, in Chemical Formula 1, x may be an integer from to 2; M may be selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; n is an integer from 1 to 8; N may be F, Cl, Br, or I or a ligand consisting of a combination of two or more selected from the group consisting of F, Cl, Br, and I; m may be an integer from 0 to 5; L may be H, C, N, O, P, or S or a ligand consisting of a combination of two or more selected from the group consisting of H, C, N, O, and P. In this case, the desired effects of the present invention may be effectively expressed, and resistivity may be improved.

n may be preferably an integer from 1 to 7, more preferably an integer from 1 to 6. Within this range, process by-products may be reduced, and the degree of adsorption to a substrate may be further increased. In addition, N may be a halogen element, preferably fluorine, chlorine, or bromine, more preferably fluorine or chlorine. Within this range, process by-products may be reduced, and the degree of adsorption to a substrate may be further increased. In addition, N may be, for example, chlorine. In this case, thin film crystallinity may be improved, and side reactions may be suppressed, thereby increasing the effect of reducing process by-products.

In Chemical Formula 1, as another preferred example, N may be iodine or bromine. In this case, the metal thin film precursor compound may be more suitable for processes requiring low temperature deposition.

As a preferred example, the metal thin film precursor compound may be a branched or cyclic compound represented by Chemical Formula 1. In Chemical Formula 1, A is carbon; B is hydrogen or an alkyl having 1 to 10 carbon atoms; X is bromine (Br) or iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are 0. In this case, the desired effects of the present invention may be effectively expressed, resistivity and thin film crystallinity may be improved, and side reactions may be suppressed, thereby increasing the effect of reducing process by-products.

The metal thin film precursor compound may be a compound containing a halogen. As a specific example, the metal thin film precursor compound may include compounds represented by Chemical Formulas 3 to 39 below. Here, the compounds represented by Chemical Formulas 3 to 39 may be independently selected or combinations thereof may be used.

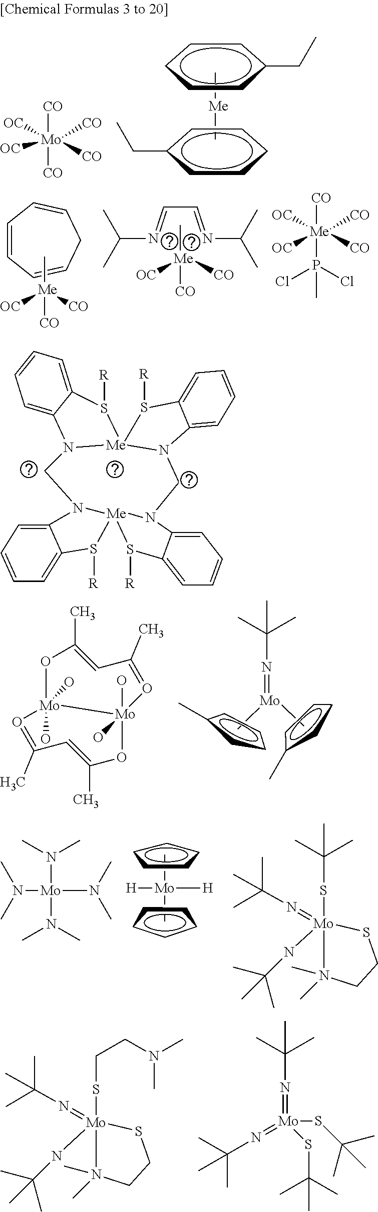

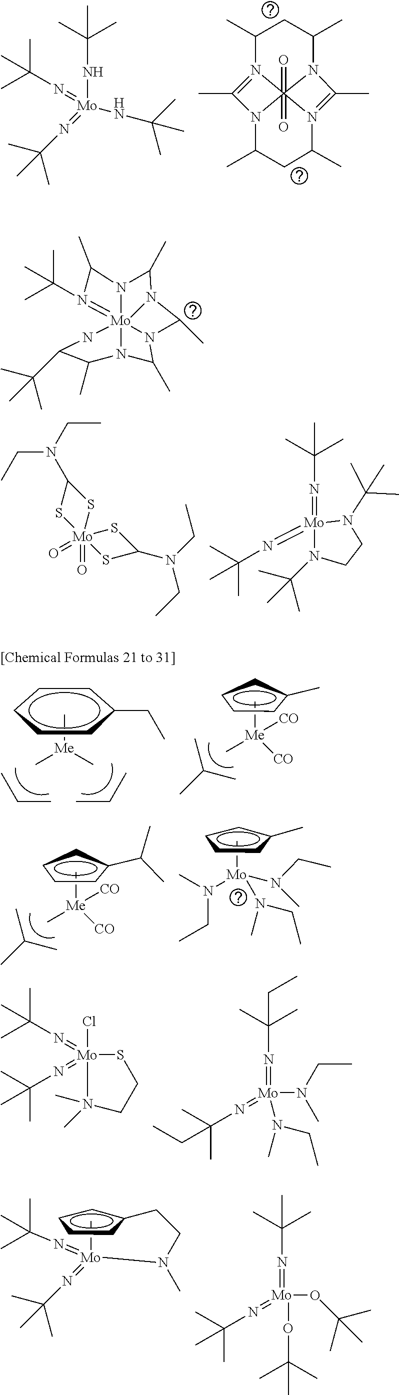

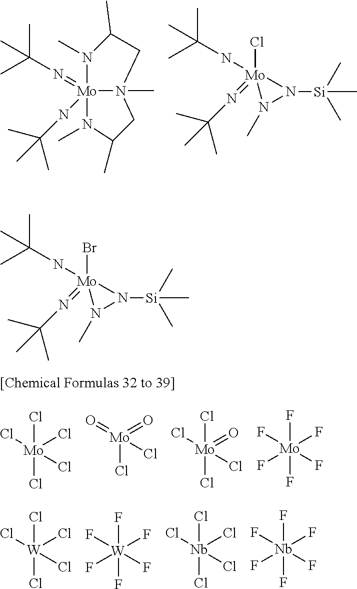

In Chemical Formulas 3 to 39, a line is a bond; carbon is located at a point where bonds meet without indicating a separate element; the number of hydrogen atoms satisfying a valence of the carbon is omitted; R′ and R″ are each hydrogen or an alkyl group having 1 to 5 carbon atoms; and R′ is connected to adjacent R′.

In addition, the metal thin film precursor composition of the present invention includes a thin film precursor compound; and a growth regulator.

The thin film precursor compound includes the above-described compound represented by Chemical Formula 1.

The growth regulator is a straight-chain, branched, cyclic, or aromatic compound represented by Chemical Formula 2 below.

AnBmXoYiZj [Chemical Formula 2]

In Chemical Formula 1, A is carbon, silicon, nitrogen, phosphorus, or sulfur; B is hydrogen, an alkyl having 1 to 10 carbon atoms, a cycloalkyl having 3 to 10 carbon atoms, or an alkoxy having 1 to 10 carbon atoms; X includes one or more of fluorine (F), chlorine (Cl), bromine (Br), and iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3. In this case, the desired effects may be realized, and the resistivity of a thin film may be improved.

The weight ratio of the growth regulator to the thin film precursor compound may be 1:99 to 99:1, 1:90 to 90:1, 1:85 to 85:1, or 1:80 to 80:1.

For example, the growth regulator may be a branched or cyclic compound represented by Chemical Formula 2. In Chemical Formula 2, A is carbon or silicon; B is hydrogen, an alkyl having 1 to 10 carbon atoms, a cycloalkyl having 3 to 10 carbon atoms, or an alkoxy having 1 to 10 carbon atoms; X is fluorine (F), chlorine (Cl), bromine (Br), or iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are 0. In this case, the desired effects of the present invention may be effectively expressed, and resistivity may be improved.

X may be a halogen element, preferably fluorine, chlorine, bromine, or iodine, more preferably chlorine or bromine. Within this range, process by-products may be reduced, and the degree of adsorption to a substrate may be further increased. In addition, for example, X may be chlorine. In this case, thin film crystallinity may be improved, and side reactions may be suppressed, thereby reducing process by-products.

In Chemical Formula 2, as another preferred example, X may be iodine or bromine. In this case, the growth regulator may be more suitable for processes requiring low temperature deposition.

As a preferred example, the growth regulator may be a branched or cyclic compound represented by Chemical Formula 2. In Chemical Formula 2, A is carbon; B is hydrogen or an alkyl having 1 to 10 carbon atoms; X is bromine (Br) or iodine (I) ; Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are 0. In this case, the desired effects of the present invention may be effectively expressed, and resistivity may be improved.

As a preferred example, the growth regulator may be a branched or cyclic compound represented by Chemical Formula 2. In Chemical Formula 2, A is carbon; B is hydrogen or an alkyl having 1 to 10 carbon atoms; X is bromine (Br) or iodine (I) ; Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are 0. In this case, the desired effects of the present invention may be effectively expressed, resistivity and thin film crystallinity may be improved, and side reactions may be suppressed, thereby increasing the effect of reducing process by-products.

As another preferred example, the growth regulator includes a hydrocarbon compound including an electron acceptor terminal group. The hydrocarbon compound may be a material that is not reactive with the thin film precursor compound. In this case, when the growth regulator is used, the adsorption structure and growth rate of the thin film precursor compound may be adjusted, process by-products may be reduced, and deposition rate may be adjusted to appropriately reduce thin film growth rate. Thus, even when a thin film is formed on a substrate having a complicated structure, step coverage and film quality may be improved, corrosion or deterioration may be prevented, the crystallinity of a thin film may be improved, and thus the resistivity characteristics and electrical properties of the thin film may be improved.

The hydrocarbon compound may preferably be a compound having a structure in which one or more selected from the group consisting of alkanes and cycloalkanes are replaced with an electron acceptor terminal group. In this case, reactivity and solubility may be low, and moisture may be easily controlled. In addition, when forming a thin film, step coverage may be improved in a high aspect ratio trench structure.

As a more preferred example, the hydrocarbon compound may include a C1 to C10 alkane or a C3 to C10 cycloalkane, preferably a C3 to C10 cycloalkane. In this case, reactivity and solubility may be reduced, and moisture management may be easy.

In the present disclosure, C1, C3, and the like mean the carbon number.

The cycloalkane may preferably be a C3 to C10 monocycloalkane. Among the monocycloalkanes, cyclopentane exists in a liquid state at room temperature and has the highest vapor pressure, and thus is preferable in a vapor deposition process. However, the present invention is not limited thereto.

Unless otherwise specified, the term “electron acceptor terminal group” used in the present invention refers to a functional group that may provide improvement in film quality when combined with a thin film precursor compound.

For example, the electron acceptor terminal group may be an ortho-oriented or para-oriented deactivator.

Unless otherwise specified, the term “ortho-oriented or para-oriented deactivator” refers to a deactivator that exhibits orientation at the ortho or para position thereof when using a precursor compound having a benzene ring.

As another example, the electron acceptor terminal group may be an electron accepter having an electronegativity of 2.0 to 4.0, preferably 2.0 to 3.0.

Unless otherwise specified, when a precursor compound without a benzene ring is used, the compound may have a functional group that satisfies the corresponding electronegativity range.

As a specific example, the electron acceptor terminal group may be a halogen element, preferably fluorine, chlorine, bromine, or iodine, more preferably bromine or iodine. Within this range, the effect of reducing process by-products and improving step coverage may further increase. In addition, X may be, for example iodine. In this case, the growth regulator may be more suitable for processes requiring low temperature deposition. In particular, iodine may be used alone as X. In this case, the film quality of a thin film may be further improved by preventing excessive increase in impurities.

As another preferred example, the growth regulator may be Cl, Br, or I, or may include a halide terminal group consisting of a combination of two or more selected from the group consisting of Cl, Br, and I. In this case, the desired effects of the present invention may be effectively expressed, resistivity and thin film crystallinity may be improved, and side reactions may be suppressed, thereby increasing the effect of reducing process by-products.

As a more preferred example, when the growth regulator has a skeleton of tert-carbocation, impurities may be prevented from remaining after thin film formation. In particular, the amount of residual carbon may be greatly reduced.

When the reactivity between the hydrocarbon compound and the thin film precursor compound is measured, an H-NMR spectrum measured before mixing the hydrocarbon compound and the thin film precursor compound is compared with an H-NMR spectrum measured after pressurizing for 1 hour a mixture obtained by mixing the hydrocarbon compound and the thin film precursor compound in a molar ratio of 1:1. At this time, when the integrated value of the generated NMR peaks is referred to as the amount of impurities, the amount (%) of the impurities is less than 0.1%. Thus, when the growth regulator is used, the adsorption structure and growth rate of the thin film precursor compound may be adjusted, process by-products may be reduced, and deposition rate may be adjusted to appropriately reduce thin film growth rate. Thus, even when a thin film is formed on a substrate having a complicated structure, step coverage and film quality may be improved, corrosion or deterioration may be prevented, the crystallinity of a thin film may be improved, and thus the resistivity characteristics and electrical properties of the thin film may be improved.

Due to the above-mentioned reactivity, the growth regulator easily controls the viscosity or vapor pressure of the thin film precursor compound, but does not interfere with the behavior of the thin film precursor compound.

For example, the hydrocarbon compound exhibiting the above-described reactivity and including an electron acceptor terminal group may be a halogen-substituted straight-chain or branched alkane compound or cycloalkane compound.

As a specific example, the hydrocarbon compound may include one or more selected from the group consisting of tert-butyl iodide, 1-iodobutane, 2-iodobutane, 2-iodo-3-methyl butane, 3-iodo-2,4-dimethyl pentane, cyclohexyl iodide, cyclopentyl iodide, tert-butyl bromide, 1-bromobutane, 2-bromobutane, 2-bromo-3-methyl butane, 3-bromo-2,4-dimethyl pentane, cyclohexyl bromide, cyclopentyl bromide, tert-butyl chloride, 1-chlorobutane, 2-chlorobutane, 2-chloro-3-methyl butane, 3-chloro-2,4-dimethyl pentane, cyclohexyl chloride, and cyclopentyl chloride, preferably one or more selected from the group consisting of tert-butyl iodide, tert-butyl bromide, tert-butyl chloride, 1-iodobutane, 2-iodobutane, 1-bromobutane, 2-bromobutane, 1-chlorobutane, and 2-chlorobutane. In this case, as the growth regulator, the hydrocarbon compound may effectively protect the surface of a substrate and may effectively remove process by-products while controlling the adsorption structure and growth rate of the thin film precursor compound.

As described above, the hydrocarbon compound may include halogen-substituted hydrocarbons, as a specific example, compounds represented by Chemical Formulas 40 to 60 below. The compounds represented by Chemical Formulas 40 to 60 may be selected independently or used in combination.

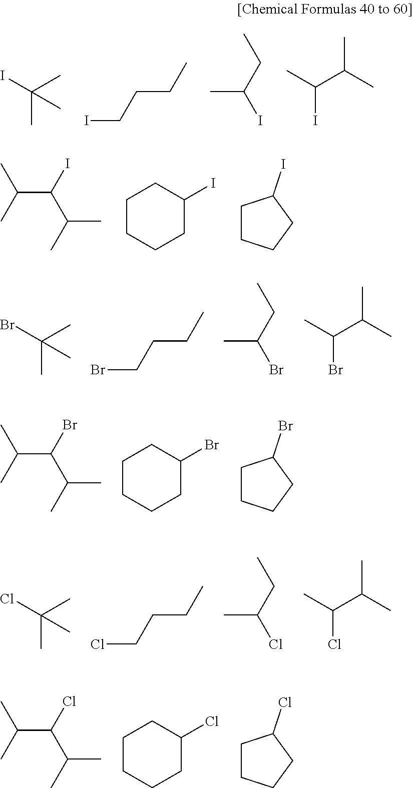

In Chemical Formulas 40 to 60, a line is a bond; carbon is located at a point where bonds meet without indicating a separate element; and the number of hydrogen atoms satisfying a valence of the carbon is omitted.

The metal thin film precursor composition, the metal thin film precursor compound, and the growth regulator are preferably used in an atomic layer deposition (ALD) process, a plasma atomic layer deposition (PEALD) process, a chemical vapor deposition (CVD) process, or a plasma chemical vapor deposition (PECVD) process. In this case, the growth regulator may effectively protect the surface of a substrate without interfering with adsorption of the thin film precursor compound, and process by-products may be effectively removed.

Preferably, the growth regulator may be in a liquid state at room temperature (22° C.) and may have a density of 0.8 to 2.5 g/cm³ or 0.8 to 1.7 g/cm³, a vapor pressure (20° C.) of 0.1 to 300 mmHg or 1 to 300 mmHg, and a water solubility (25° C.) of 200 mg/L or less. Within this range, step coverage and the thickness uniformity and quality of a thin film may be excellent.

More preferably, the growth regulator may have a density of 0.75 to 2.0 g/cm³ or 0.8 to 1.7 g/cm³, a vapor pressure (20° C.) of 0.1 to 1,000 mmHg, and a water solubility (25° C.) of 2,000 mg/L or less. Within this range, step coverage and the thickness uniformity and quality of a thin film may be improved.

In addition, as another preferred example, the method of forming a metal thin film of the present invention includes a step of injecting the thin film precursor composition into an ALD chamber and adsorbing the metal thin film precursor composition on the surface of a loaded substrate. In this case, thin film growth rate may be increased appropriately, and process by-products generated during thin film formation may be effectively removed, thereby reducing impurities in a thin film and greatly improving crystallinity.

In the method of forming a thin film, a reducing agent, a nitrifying agent, or an oxidizing agent is used as the reaction gas.

For example, in the method of forming a thin film, deposition temperature may be 50 to 700° C., preferably 250 to 500° C., as a specific example, 250 to 450° C., 280 to 450° C., or 350 to 420° C. Within this range, thin film resistivity and step coverage may be greatly improved.

In Chemical Formula 1, M is titanium, tungsten, molybdenum, silicon, hafnium, zirconium, indium, germanium, or niobium, preferably titanium, tungsten, molybdenum, or niobium.

In Chemical Formula 1, N is a halogen element, preferably fluorine, chlorine, bromine, or iodine, more preferably fluorine, chlorine, or bromine. Within this range, process by-products may be reduced, and the degree of adsorption to a substrate may be further increased. In addition, N may be, for example, fluorine or chlorine. In this case, thin film crystallinity may be improved, side reactions may be suppressed, and the effect of reducing process by-products may be greatly increased.

In Chemical Formula 1, L may be H, C, N, O, P, or S or a ligand consisting of a combination of two or more selected from the group consisting of H, C, N, O, and P. In this case, thin film crystallinity may be improved, side reactions may be suppressed, and the effect of reducing process by-products may be greatly increased.

The compound represented by Chemical Formula 1 is a compound having a halogen functional group at a central metal thereof. As a specific example, the compound represented by Chemical Formula 1 may include one or more selected from the group consisting of molybdenum (V) chloride (MoCl₅), molybdenum oxytetrachloride (MoOCl₄), molybdenum dichloride dioxide (MoO₂Cl₂), molybdenum (VI) fluoride (MoF₆), tungsten (VI) chloride (WCl₆), tungsten (VI) fluoride (WF₆), niobium (V) chloride (NbCl₅), and niobium (V) fluoride (NbF₆). In this case, process by-products may be efficiently removed, step coverage may be improved, and adsorption to a substrate may be promoted.

The compound represented by Chemical Formula 1 is a halogen-substituted tertiary alkyl compound. As a specific example, the halogen-substituted tertiary alkyl compound may include one or more selected from the group consisting of tetrachlorotitanium, 2-chloro-3-methyltitanium, 2-chloro-2-methyltitanium, tetrabromotitanium, 3-bromo-3-methyltitanium, 3-bromo-3-methyltitanium, tetrachlorotitanium, 2-chloro-3-methyltungsten, 2-chloro-2-methyltungsten, tetrabromotungsten, 3-bromo-3-methyltungsten, 3-bromo-3-methyltungsten, tetrachloromolybdenum, 2-chloro-3-methylmolybdenum, 2-chloro-2-methylmolybdenum, tetrabromomolybdenum, 3-bromo-3-methylmolybdenum, 3-bromo-3-methylmolybdenum, tetrachlorohafnium, 2-chloro-3-methylhafnium, 2-chloro-2-methylhafnium, tetrabromohafnium, 3-bromo-3-methylhafnium, 3-bromo-3-methylhafnium, tetrachlorohafnium, 2-chloro-3-methylzirconium, 2-chloro-2-methylzirconium, tetrabromozirconium, 3-bromo-3-methylzirconium, 3-bromo-3-methylzirconium, tetrachloroindium, 2-chloro-3-methylindium, 2-chloro-2-methylindium, tetrabromoindium, 3-bromo-3-methylindium, and 3-bromo-3-methylindium. In this case, process by-products may be efficiently removed, step coverage may be improved, and adsorption to a substrate may be promoted.

The compounds (or conductive compounds) represented by Chemical Formula 1 are described with specific examples, but the present invention is not limited thereto. Thin film precursor compounds commonly used in an atomic layer deposition (ALD) method may be used without particular limitation.

Unless otherwise specified, the term “conductive compound” used in the present invention refers to a material that has electron donors or acceptors and has conductivity, and may affect depending on the structure and charge transfer oxidation state thereof.

As a specific example, the conductive compound may include one or more selected from the group consisting of metal thin film precursor compounds, metal oxide film precursor compounds, metal nitride film precursor compounds, and silicon nitride film precursor compounds, and the metal may preferably include one or more selected from the group consisting of tungsten, cobalt, chromium, aluminum, hafnium, vanadium, niobium, germanium, lanthanides, actinoids, gallium, tantalum, zirconium, ruthenium, copper, titanium, nickel, iridium, molybdenum, platinum, ruthenium, and niobium.

For example, the metal film precursor, the metal oxide film precursor, and the metal nitride film precursor may independently include one or more selected from the group consisting of metal halides, metal alkoxides, alkyl metal compounds, metal amino compounds, metal carbonyl compounds, and substituted or unsubstituted cyclopentadienyl metal compounds, without being limited thereto.

For example, the metal oxide film precursor may be selected from the group consisting of PtO, PtO₂, RuO₂, IrO₂, SrRuO₃, BaRuO₃, and CaRuO₃.

As a specific example, the metal film precursor, the metal oxide film precursor, and the metal nitride film precursor may independently include one or more selected from the group consisting of tetrachlorotitanium, tetrachlorogemanium, tetrachlorotin, tris (isopropyl) ethylmethyl aminogermanium, tetraethoxylgermanium, tetramethyl tin, tetraethyl tin, bisacetylacetonate tin, trimethylaluminum, tetrakis (dimethylamino) germanium, bis (n-butylamino) germanium, tetrakis (ethylmethylamino) tin, tetrakis (dimethylamino) tin, dicobalt octacarbonyl (Co₂(CO)₈), biscyclopentadienylcobalt (Cp2Co), cobalt tricarbonyl nitrosyl (Co(CO)₃NO), and cabalt dicarbonyl cyclopentadienyl (CpCo(CO)₂), without being limited thereto.

For example, the silicon nitride film precursor may include one or more selected from the group consisting of SiH₄, SiCl₄, SiF₄, SiCl₂H₂, Si₂Cl₆, TEOS, DIPAS, BTBAS, (NH₂)Si(NHMe)₃, (NH₂)Si(NHEt)₃, (NH₂)Si(NHⁿPr)₃, (NH₂)Si(NHⁱPr)₃, (NH₂)Si(NHⁿBu)₃, (NH₂)Si(NHⁱBu)₃, (NH₂)Si(NH^{t}Bu)₃, (NMe₂)Si(NHMe)₃, (NMe₂)Si(NHEt)₃, (NMe₂)Si(NHⁿPr)₃, (NMe₂)Si(NHⁱPr)₃, (NMe₂)Si(NHⁿBu)₃, (NMe₂)Si(NHⁱBu)₃, (NMe₂)Si(NH^{t}Bu)₃, (NEt₂)Si(NHMe)₃, (NEt₂)Si(NHEt)₃, (NEt₂)Si(NHⁿPr)₃, (NEt₂)Si(NHⁱPr)₃, (NEt₂)Si(NHⁿBu)₃, (NEt₂)Si(NHⁱBu)₃, (NEt₂)Si(NH^{t}Bu)₃, (NⁿPr₂)Si(NHMe)₃, (NⁿPr₂)Si(NHEt)₃, (NⁿPr₂)Si(NHⁿPr)₃, (NⁿPr₂)Si(NHⁱPr)₃, (NⁿPr₂)Si(NHⁿBu)₃, (NⁿPr₂)Si(NHⁱBu)₃, (NⁿPr₂)Si(NH^{t}Bu)₃, (NⁱPr₂)Si(NHMe)₃, (NⁱPr₂)Si(NHEt)₃, (NⁱPr₂)Si(NHⁿPr)₃, (NⁱPr₂)Si(NHⁱPr)₃, (NⁱPr₂)Si(NHⁿBu)₃, (NⁱPr₂)Si(NHⁱBu)₃, (NⁱPr₂)Si(NH^{t}Bu)₃, (NⁿBu₂)Si(NHMe)₃, (NⁿBu₂)Si(NHEt)₃, (NⁿBu₂)Si(NHⁿPr)₃, (NⁿBu₂)Si(NHⁱPr)₃, (NⁿBu₂)Si(NHⁿBu)₃, (NⁿBu₂)Si(NHⁱBu)₃, (NⁿBu₂)Si(NH^{t}Bu)₃, (NⁱBu₂)Si(NHMe)₃, (NⁱBu₂)Si(NHEt)₃, (NⁱBu₂)Si(NHⁿPr)₃, (NⁱBu₂)Si(NHⁱPr)₃, (NⁱBu₂)Si(NHⁿBu)₃, (NⁱBu₂)Si(NHⁱBu)₃, (NⁱBu₂)Si(NH^{t}Bu)₃, (N^{t}Bu₂)Si(NHMe)₃, (N^{t}Bu₂)Si(NHEt)₃, (N^{t}Bu₂)Si(NHⁿPr)₃, (N^{t}Bu₂)Si(NHⁱPr)₃, (N^{t}Bu₂)Si(NHⁿBu)₃, (N^{t}Bu₂)Si(NHⁱBu)₃, (N^{t}Bu₂)Si(NH^{t}Bu)₃, (NH₂)₂Si(NHMe)₂, (NH₂)₂Si(NHEt)₂, (NH₂)₂Si(NHⁿPr)₂, (NH₂)₂Si(NHⁱPr)₂, (NH₂)₂Si(NHⁿBu)₂, (NH₂)₂Si(NHⁱBu)₂, (NH₂)₂Si(NH^{t}Bu)₂, (NMe₂)₂Si(NHMe)₂, (NMe₂)₂Si(NHEt)₂, (NMe₂)₂Si(NHⁿPr)₂, (NMe₂)₂Si(NHⁱPr)₂, (NMe₂)₂Si(NHⁿBu)₂, (NMe₂)₂Si(NHⁱBu)₂, (NMe₂)₂Si(NH^{t}Bu)₂, (NEt₂)₂Si(NHMe)₂, (NEt₂)₂Si(NHEt)₂, (NEt₂)₂Si(NHⁿPr)₂, (NEt₂)₂Si(NHⁱPr)₂, (NEt₂)₂Si(NHⁿBu)₂, (NEt₂)₂Si(NHⁱBu)₂, (NEt₂)₂Si(NH^{t}Bu)₂, (NⁿPr₂)₂Si(NHMe)₂, (NⁿPr₂)₂Si(NHEt)₂, (NⁿPr₂)₂Si(NHⁿPr)₂, (NⁿPr₂)₂Si(NHⁱPr)₂, (NⁿPr₂)₂Si(NHⁿBu)₂, (NⁿPr₂)₂Si(NHⁱBu)₂, (NⁿPr₂)₂Si(NH^{t}Bu)₂, (NⁱPr₂)₂Si(NHMe)₂, (NⁱPr₂)₂Si(NHEt)₂, (NⁱPr₂)₂Si(NHⁿPr)₂, (NⁱPr₂)₂Si(NHⁱPr)₂, (NⁱPr₂)₂Si(NHⁿBu)₂, (NⁱPr₂)₂Si(NHⁱBu)₂, (NⁱPr₂)₂Si(NH^{t}Bu)₂, (NⁿBu₂)₂Si(NHMe)₂, (NⁿBu₂)₂Si(NHEt)₂, (NⁿBu₂)₂Si(NHⁿPr)₂, (NⁿBu₂)₂Si(NHⁱPr)₂, (NⁿBu₂)₂Si(NHⁿBu)₂, (NⁿBu₂)₂Si(NHⁱBu)₂, (NⁿBu₂)₂Si(NH^{t}Bu)₂, (NⁱBu₂)₂Si(NHMe)₂, (NⁱBu₂)₂Si(NHEt)₂, (NⁱBu₂)₂Si(NHⁿPr)₂, (NⁱBu₂)₂Si(NHⁱPr)₂, (NⁱBu₂)₂Si(NHⁿBu)₂, (NⁱBu₂)₂Si(NHⁱBu)₂, (NⁱBu₂)₂Si(NH^{t}Bu)₂, (N^{t}Bu₂)₂Si(NHMe)₂, (N^{t}Bu₂)₂Si(NHEt)₂, (N^{t}Bu₂)₂Si(NHⁿPr)₂, (N^{t}Bu₂)₂Si(NHⁱPr)₂, (N^{t}Bu₂)₂Si(NHⁿBu)₂, (N^{t}Bu₂)₂Si(NHⁱBu)₂, (N^{t}Bu₂)₂Si(NH^{t}Bu)₂, Si(HNCH₂CH₂NH)₂, Si(MeNCH₂CH₂NMe)₂, Si(EtNCH₂CH₂NEt)₂, Si(ⁿPrNCH₂CH₂NⁿPr)₂, Si(ⁱPrNCH₂CH₂NⁱPr)₂, Si(ⁿBuNCH₂CH₂NⁿBu)₂, Si(ⁱBuNCH₂CH₂NⁱBu)₂, Si(^{t}BuNCH₂CH₂N^{t}Bu)₂, Si(HNCHCHNH)₂, Si(MeNCHCHNMe)₂, Si(EtNCHCHNEt)₂, Si(ⁿPrNCHCHNⁿPr)₂, Si(ⁱPrNCHCHNⁱPr)₂, Si(ⁿBuNCHCHNⁿBu)₂, Si(ⁱBuNCHCHNⁱBu)₂, Si(^{t}BuNCHCHN^{t}Bu)₂, (HNCHCHNH)Si(HNCH₂CH₂NH), (MeNCHCHNMe)Si(MeNCH₂CH₂NMe), (EtNCHCHNEt)Si(EtNCH₂CH₂NEt), (ⁿPrNCHCHNⁿPr)Si(ⁿPrNCH₂CH₂NⁿPr), (ⁱPrNCHCHNⁱPr)Si(ⁱPrNCH₂CH₂NⁱPr), (ⁿBuNCHCHNⁿBu)Si(ⁿBuNCH₂CH₂NⁿBu), (ⁱBuNCHCHNⁱBu)Si(ⁱBuNCH₂CH₂NⁱBu), (^{t}BuNCHCHN^{t}Bu)Si(BuNCH₂CH₂N^{t}Bu), (NH^{t}Bu)₂Si(HNCH₂CH₂NH), (NH^{t}Bu)₂Si(MeNCH₂CH₂NMe), (NH^{t}Bu)₂Si(EtNCH₂CH₂NEt), (NH^{t}Bu)₂Si(ⁿPrNCH₂CH₂NⁿPr), (NH^{t}Bu)₂Si(ⁱPrNCH₂CH₂NⁱPr), (NH^{t}Bu)₂Si(ⁿBuNCH₂CH₂NⁿBu), (NH^{t}Bu)₂Si(ⁱBuNCH₂CH₂NⁱBu), (NH^{t}Bu)₂Si(^{t}BuNCH₂CH₂N^{t}Bu), (NH^{t}Bu)₂Si(HNCHCHNH), (NH^{t}Bu)₂Si(MeNCHCHNMe), (NH^{t}Bu)₂Si(EtNCHCHNEt), (NH^{t}Bu)₂Si(ⁿPrNCHCHNⁿPr), (NH^{t}Bu)₂Si(ⁱPrNCHCHNⁱPr), (NH^{t}Bu)₂Si(ⁿBuNCHCHNⁿBu), (NH^{t}Bu)₂Si(ⁱBuNCHCHNⁱBu), (NH^{t}Bu)₂Si(^{t}BuNCHCHN^{t}Bu), (ⁱPrNCH₂CH₂NⁱPr)Si(NHMe)₂, (ⁱPrNCH₂CH₂NⁱPr)Si(NHEt)₂, (ⁱPrNCH₂CH₂NⁱPr)Si(NHⁿPr)₂, (ⁱPrNCH₂CH₂NⁱPr)Si(NHⁱPr)₂, (ⁱPrNCH₂CH₂NⁱPr)Si(NHⁿBu)₂, (ⁱPrNCH₂CH₂NⁱPr)Si(NHⁱBu)₂, (ⁱPrNCH₂CH₂NⁱPr)Si(NH^{t}Bu)₂, (ⁱPrNCHCHNⁱPr)Si(NHMe)₂, (ⁱPrNCHCHNⁱPr)Si(NHEt)₂, (ⁱPrNCHCHNⁱPr)Si(NHⁿPr)₂, (ⁱPrNCHCHNⁱPr)Si(NHⁱPr)₂, (ⁱPrNCHCHNⁱPr)Si(NHⁿBu)₂, (ⁱPrNCHCHNⁱPr)Si(NHⁱBu)₂, and (ⁱPrNCHCHNⁱPr)Si(NH^{t}Bu)₂, without being limited thereto.

Here, ⁿPr means n-propyl, ⁱPr means iso-propyl, ⁿBu means n-butyl, ⁱBu means iso-butyl, and tBu means tert-butyl.

As a preferred example, the thin film precursor compound may include one or more selected from the group consisting of TiCl₄, (Ti(CpMe₅)(OMe)₃), Ti(CpMe₃)(OMe)₃, Ti(OMe)₄, Ti(OEt)₄, Ti(OtBu)₄, Ti(CpMe)(OiPr)₃, TTIP(Ti(OiPr)₄, TDMAT (Ti(NMe₂)₄), Ti(CpMe) {N(Me₂)₃}, Pt, Ru, Ir, PtO, PtO₂, RuO₂, IrO₂, SrRuO₃, BaRuO₃, and CaRuO₃. In this case, the required effects of the present invention may be fully achieved.

The titanium tetrahalide may be used as a metal precursor of a composition for forming a thin film. For example, the titanium tetrahalide may be at least one selected from the group consisting of TiF₄, TiCl₄, TiBr₄, and TiI₄. As a preferred example, considering economic feasibility, the titanium tetrahalide is TiCl₄, but the present invention is not limited thereto.

Since the titanium tetrahalide does not decompose at room temperature due to excellent thermal stability thereof and exists in a liquid state, the titanium tetrahalide may be used as a precursor for depositing a thin film according to atomic layer deposition (ALD).

For example, the thin film precursor compound may be fed into a chamber after being mixed with a non-polar solvent (excluding non-polar solvents that overlap with hydrocarbon compounds). In this case, the viscosity of the thin film precursor compound or vapor pressure may be easily adjusted.

The non-polar solvent may preferably include one or more selected from the group consisting of alkanes and cycloalkanes. In this case, step coverage may be improved even when deposition temperature increases when forming a thin film while containing an organic solvent having low reactivity and solubility and capable of easy moisture management.

As a more preferred example, the non-polar solvent may include a C1 to C10 alkane or a C3 to C10 cycloalkane, preferably a C3 to C10 cycloalkane. In this case, reactivity and solubility may be reduced, and moisture management may be easy.

In the present disclosure, C1, C3, and the like mean the carbon number.

The cycloalkane may preferably be a C3 to C10 monocycloalkane. Among the monocycloalkanes, cyclopentane exists in a liquid state at room temperature and has the highest vapor pressure, and thus is preferable in a vapor However, the present invention is not deposition process. limited thereto.

For example, the non-polar solvent has a water solubility (25° C.) of 200 mg/L or less, preferably 50 to 200 mg/L, more preferably 135 to 175 mg/L. Within this range, reactivity to the thin film precursor compound may be low, and moisture management may be easy.

In the present disclosure, solubility may be measured without particular limitation according to measurement methods or standards commonly used in the art to which the present invention pertains. For example, solubility may be measured according to the HPLC method using a saturated solution.

Based on a total weight of the thin film precursor compound and the non-polar solvent, the non-polar solvent may be included in an amount of preferably 5 to 95% by weight, more preferably 10 to 90% by weight, still more preferably 40 to 90% by weight, most preferably 70 to 90% by weight.

When the content of the non-polar solvent exceeds the above range, impurities are generated to increase resistance and impurity levels in a thin film. When the content of the non-polar solvent is less than the above range, an effect of improving step coverage and reducing an impurity such as chlorine (Cl) ion due to addition of the solvent may be reduced.

Preferably, the compound or conductive compound represented by Chemical Formula 1 may be liquid at room temperature (22° C.), and may has a density of 0.8 to 2.5 g/cm³ or 0.8 to 1.5 g/cm³ and a vapor pressure (20° C.) of 0.1 to 300 mmHg or 1 to 300 mmHg. Within this range, step coverage and the thickness uniformity and quality of a thin film may be improved.

More preferably, the compound or conductive compound represented by Chemical Formula 1 may have a density of 0.7 to 2.0 g/cm³ or 0.8 to 1.8 g/cm³ and a vapor pressure (20° C.) of 0.1 to 1,000 mmHg. Within this range, step coverage and the thickness uniformity and quality of a thin film may be improved.

When the growth regulator and the thin film precursor compound are fed into a chamber, the feeding ratio (mg/cycle) of the growth regulator to the thin film precursor compound may be preferably 1:0.1 to 1:20, more preferably 1:0.2 to 1:15, still more preferably 1:0.5 to 1:12, still more preferably 1:0.7 to 1:10. Within this range, the effect of improving step coverage and the effect of reducing process by-products may be greatly increased.

The precursor composition consisting of the growth regulator and the thin film precursor compound is preferably used in an atomic layer deposition (ALD) process, a plasma atomic layer deposition (PEALD) process, a chemical vapor deposition (CVD) process, or a plasma chemical vapor deposition (PECVD) process. In this case, process by-products may be significantly reduced, step coverage may be excellent, thin film density may be improved, and the electrical properties of a thin film may be excellent.

The method of forming a thin film of the present invention includes a step of injecting the precursor composition into a chamber and adsorbing the precursor composition on the surface of a loaded substrate. In this case, side reactions may be reduced during thin film formation, thin film growth rate may be controlled, process by-products in a thin film may be reduced, corrosion or deterioration may be prevented, and the crystallinity of a thin film may be improved. Thus, even when a thin film is formed on a substrate having a complicated structure, step coverage and the electrical properties of the thin film may be greatly improved.

In the step of adsorbing the precursor composition on the surface of a substrate, feeding time for the thin film precursor composition, the metal thin film precursor compound constituting the thin film precursor composition, or the growth regulator is preferably 0.01 to 10 seconds, more preferably 0.02 to 5 seconds, still more preferably 0.04 to 3 seconds, still more preferably 0.05 to 2 seconds per cycle. Within this range, thin film growth rate may be reduced, and step coverage and economics may be excellent.

In the present disclosure, the feeding time for the precursor composition is based on a chamber volume of 15 to 20 L and a flow rate of 0.5 to 100 mg/s, more specifically, a chamber volume of 18 L and a flow rate of 1 to 25 mg/s.

As a preferred example, the method of forming a thin film may include step i) of vaporizing the precursor composition and adsorbing the precursor composition on the surface of a substrate loaded in a chamber; step ii) of performing first purging of the inside of the chamber using a purge gas; step iii) of supplying a reaction gas into the chamber; and step iv) of performing second purging of the inside of the chamber using a purge gas. At this time, steps i) to iv) may be performed as a unit cycle and, the cycle may be repeated until a thin film having a desired thickness is obtained. In the cycle, when the growth regulator of the present invention and the thin film precursor compound are fed at the same time and adsorbed to a substrate, even when deposited at low temperature, process by-products may be effectively removed, the resistivity of a thin film may be improved, and step coverage may be greatly improved.

As a preferred example, according to the method of forming a thin film of the present invention, in one cycle, the growth regulator of the present invention and the thin film precursor compound may be fed at the same time, and the growth regulator and the thin film precursor compound may be adsorbed on the substrate. In this case, even when a thin film is deposited at low temperatures, thin film growth rate may be appropriately reduced, thereby greatly reducing process by-products and greatly improving step coverage. In addition, the crystallinity of a thin film may be increased, thereby improving the resistivity of the thin film. In addition, even when the thin film is used in a semiconductor device having a high aspect ratio, due to improvement of the thickness uniformity of the thin film, the reliability of the semiconductor device may be secured.

For example, according to the method of forming a thin

film, when depositing the thin film precursor compound and simultaneously adsorbing the growth regulator, when necessary, the unit cycle may be repeated 1 to 99,999 times, preferably 10 to 10,000 times, more preferably 50 to 5,000 times, still more preferably 100 to 2,000 times. Within this range, a thin film having a desired thickness may be obtained, and the effect of improving physical properties such as resistivity to be achieved in the present invention may be sufficiently obtained.

In addition, as shown in examples to be described later, when the growth regulator is adsorbed before deposition of the thin film precursor compound, or when the growth regulator is adsorbed after deposition of the thin film precursor compound, effect of the improving physical properties including resistivity, which is obtained in the case of simultaneously adding and depositing the growth regulator and the thin film precursor compound, may also be obtained.

When the growth regulator and the thin film precursor compound are adsorbed on a substrate at the same time or sequentially, in the step of purging the non-adsorbed precursor composition, the amount of a purge gas introduced into the chamber is not particularly limited as long as the purge gas is sufficient to remove the non-adsorbed precursor composition. For example, the amount of a purge gas may be 10 to 100,000 times, preferably 50 to 50,000 times, more preferably 100 to 10,000 times. Within this range, the non-adsorbed precursor composition may be sufficiently removed. Thus, a thin film may be formed uniformly, and deterioration of film quality may be prevented. Here, the feeding amounts of the purge gas and the precursor composition are based on one cycle. The volume of the precursor composition is the volume of the vaporized metal thin film precursor composition.

As a specific example, when the precursor composition is injected at a flow rate of 1.66 mL/s and an injection time of 0.5 sec (per one cycle) and the purge gas is injected at a flow rate of 166.6 mL/s and an injection time of 3 sec (per one cycle) in the step of purging the non-adsorbed precursor composition, the injection amount of the purge gas is 602 times that of the metal thin film precursor composition.

In addition, for example, in the purging step performed immediately after the reaction gas supply step, based on the volume of the reaction gas introduced into the chamber, the amount of the purge gas introduced into the chamber may be 10 to 10,000 times, preferably 50 to 50,000 times, more preferably 100 to 10,000 times. Within this range, the desired effects may be fully achieved. Here, the input amounts of the purge gas and reaction gas are each based on one cycle.

The metal thin film precursor composition and the thin film precursor compound may preferably be transferred into an ALD chamber, a CVD chamber, a PEALD chamber, or a PECVD chamber by a VFC method, a DLI method, or an LDS method. More preferably, the metal thin film precursor composition and the thin film precursor compound are transferred to an ALD chamber by an LDS method.

When the growth regulator and the thin film precursor compound constituting the precursor composition are fed into a chamber, the feeding ratio (mg/cycle) of the growth regulator to the thin film precursor compound may be preferably 1:0.1 to 1:20, more preferably 1:0.2 to 1:15, still more preferably 1:0.5 to 1:12, still more preferably 1:0.7 to 1:10. Within this range, the effect of improving step coverage and the effect of reducing process by-products may be greatly increased.

For example, in the method of forming a thin film, when the precursor composition is used, the degree of improvement in resistivity (μΩ·cm) calculated by Equation 1 below is −50% or less, preferably −50% to −10%. Within this range, step coverage, resistivity characteristics, and the thickness uniformity of a thin film may be excellent.

Degree of improvement in resistivity (8)=[(Resistivity when growth regulator is used−resistivity when no growth regulator is used)/Resistivity when no growth regulator is used]×100 [Equation 1]

In Equation 1, the degree of improvement in resistivity when a growth regulator is used and the degree of improvement in resistivity when no growth regulator is used mean the conductivity properties, i.e., resistivity (μΩ·cm), of each case. For example, when the resistivity is measured, surface resistance is measured using a four-point probe, and then the resistivity is obtained based on the thickness value of a thin film.

In Equation 1, “when a growth regulator is used” means a case of adsorbing the growth regulator and the thin film precursor compound on a substrate at the same time in the thin film deposition process to form a thin film. “When no growth regulator is used” means a case of adsorbing the thin film precursor compound on a substrate without using the growth regulator in the thin film deposition process to form a thin film.

According to the method of forming a thin film, when residual halogen intensity (c/s) in a thin film having a thickness of 100 Å (10 nm) is measured according to XPS, the residual halogen intensity (c/s) may be preferably 100,000 or less, more preferably 90,000 or less, still more preferably 80,000 or less, still more preferably 76,000 or less. Within this range, the effect of preventing corrosion and deterioration may be excellent.

According to the method of forming a thin film, when residual halogen intensity (c/s) in a thin film having a thickness of 100 Å (10 nm) is measured according to secondary ion mass spectrometry (SIMS), the residual halogen intensity (c/s) may be preferably 100,000 or less, more preferably 90, 000 or less, still more preferably 80,000 or less, still more preferably 76,000 or less. Within this range, the effect of preventing corrosion and deterioration may be excellent.

In the present disclosure, purging may be performed at preferably 1,000 to 50,000 sccm (Standard Cubic Centimeter per Minute), more preferably 2,000 to 30,000 sccm, still more preferably 2,500 to 15,000 sccm. Within this range, a thin film growth rate per cycle may be controlled appropriately, and film quality may be improved by depositing a thin film in an atomic monolayer or an atomic monolayer-like layer.

The atomic layer deposition (ALD) process or the plasma atomic layer deposition (PEALD) process is very advantageous in fabricating integrated circuits (ICs) requiring a high aspect ratio, and in particular, due to a self-limiting thin film growth mechanism, excellent conformality and uniformity and precise thickness control may be achieved.

For example, in the method of forming a thin film, the deposition temperature may 50 to 700° C., preferably 300 to 700° C., more preferably 400 to 650° C., still more preferably 400 to 600° C. Within this range, an effect of growing a thin film having excellent film quality may be obtained while implementing ALD process characteristics.

For example, in the method of forming a thin film, the deposition pressure may be 0.01 to 20 Torr, preferably 0.1 to 20 Torr, more preferably 0.1 to 10 Torr, most preferably 0.1 to 7 Torr. Within this range, a thin film having a uniform thickness may be obtained.

In the present disclosure, the deposition temperature and the deposition pressure may be temperature and pressure in a deposition chamber or temperature and pressure applied to a substrate in a deposition chamber.

The method of forming a thin film may preferably include a step of increasing temperature in a chamber to a deposition temperature before introducing the thin film precursor composition or the growth regulator or metal thin film precursor compound constituting the thin film precursor composition into the chamber; and/or a step of performing purging by injecting an inert gas into a chamber before introducing the precursor composition into the chamber.

In addition, as a thin film-forming apparatus capable of implementing the method of forming a thin film, the present invention may include an thin film-forming apparatus including an ALD chamber, a first vaporizer for vaporizing a growth regulator, a first transfer means for transferring the vaporized growth regulator into the ALD chamber, a second vaporizer for vaporizing a thin film precursor compound, and a second transfer means for transferring the vaporized thin film precursor compound into the ALD chamber.

In addition, according to the present invention, the thin film-forming device may include a mixing means for mixing the vaporized growth regulator and the vaporized thin film precursor compound. The precursor composition may be premixed and then transferred into the chamber.

Here, a chamber, a vaporizer, a transfer means, and a mixing means commonly used in the art to which the present invention pertains may be used in the present invention without particular limitation.

As a specific example, the method of forming a thin film using the ALD process is described in detail as follows.

First, a substrate on which a thin film is to be formed is placed in a deposition chamber capable of performing atomic layer deposition.

The substrate may include a semiconductor substrate such as a silicon substrate or a silicon oxide substrate.

A conductive layer or an insulating layer may be further formed on the substrate.

To deposit a thin film on the substrate placed in the deposition chamber, the growth regulator and the thin film precursor compound or a mixture of the thin film precursor compound and a non-polar solvent are prepared.

Then, the prepared growth regulator and the prepared thin film precursor compound or mixture of the thin film precursor compound and a non-polar solvent are injected into a vaporizer, converted into a vapor phase, sequentially transferred to a deposition chamber, and adsorbed on the substrate. Alternatively, after preparing a composition for forming a thin film in advance, the composition is converted into a vapor phase using a vaporizer, transferred to a deposition chamber, and adsorbed on the substrate. Then, the non-adsorbed precursor composition (composition for forming a thin film) is purged.

According to one embodiment of the present invention, since a growth regulator that does not react with the metal thin film precursor compound is used, most of the growth regulator may be removed during purging.

In the present disclosure, for example, when the growth regulator and the metal thin film precursor compound (composition for forming a thin film) are transferred to a deposition chamber, a vapor flow control (VFC) method using a mass flow control (MFC) method, or a liquid delivery system (LDS) using a liquid mass flow control (LMFC) method may be used. Preferably, the LDS method is used.

In this case, one selected from argon (Ar), nitrogen (N₂), and helium (He) or a mixed gas of two or more thereof may be used as a transport gas or a diluent gas for moving the growth regulator and the metal thin film precursor compound to the substrate, but the present invention is not limited thereto.

In the present disclosure, for example, an inert gas may be used as the purge gas, and the transport gas or the dilution gas may be preferably used as the purge gas.

Next, a reaction gas is supplied. Reaction gases commonly used in the art to which the present invention pertains may be used as the reaction gas of the present invention without particular limitation. Preferably, the reaction gas may include a reducing agent, a nitrifying agent, or an oxidizing agent. A metal thin film is formed by reacting the reducing agent with the thin film precursor compound adsorbed on the substrate, a metal nitride thin film is formed by the nitrifying agent, and a metal oxide thin film is formed by the oxidizing agent.

Preferably, the reducing agent may be an ammonia gas (NH₃) or a hydrogen gas (H₂), the nitrifying agent may be a nitrogen gas (N₂), a hydrazine gas (N₂H₄), or a mixture of a nitrogen gas and a hydrogen gas, and the oxidizing agent may include one or more selected from the group consisting of H₂O, H₂O₂, O₂, O₃, and N₂O.

Next, the unreacted residual reaction gas is purged using an inert gas. Accordingly, in addition to the excess reaction gas, by-products may also be removed.

As described above, in the method of forming a thin film, the step of adsorbing a precursor composition on a substrate, the step of purging the non-adsorbed precursor composition, the step of supplying a reaction gas, and the step of purging the remaining reaction gas may be set as a unit cycle. The unit cycle may be repeatedly performed to form a thin film having a desired thickness.

As another example, in the method of forming a thin film, a step of adsorbing a metal thin film precursor compound on a substrate, a step of purging the non-adsorbed metal thin film precursor compound, a step of adsorbing a growth regulator on the substrate, a step of purging the non-adsorbed growth regulator or the physically adsorbed growth regulator, a step of supplying a reaction gas, and a step of purging the residual reaction gas may set as a unit cycle. The unit cycle may be repeated to form a thin film having a desired thickness.

As another example, in the method of forming a thin film, a step of adsorbing a growth regulator on a substrate, a step of purging the non-adsorbed growth regulator, a step of adsorbing a metal thin film precursor compound on the substrate, a step of purging the non-adsorbed metal thin film precursor compound or the physically adsorbed growth regulator, a step of supplying a reaction gas, and a step of purging the residual reaction gas may set as a unit cycle. The unit cycle may be repeated to form a thin film having a desired thickness.

For example, the unit cycle may be performed 1 to 99,999 times, preferably 10 to 1,000 times, more preferably 50 to 5,000 times, still more preferably 100 to 2,000 times. Within this range, the desired thin film properties may be effectively implemented.

In addition, the present invention provides a semiconductor substrate. The semiconductor substrate is fabricated using the method of forming a thin film of the present invention. In this case, the step coverage, thickness uniformity, resistivity characteristics, density, and electrical properties of a thin film may be excellent.

Preferably, the formed thin film has a thickness of 30 nm or less, a resistivity value of 5 to 2,000 μΩ·cm based on a thin film thickness of 10 nm, a halogen content of 10,000 ppm or less, and a step coverage of 80% or more. Within this range, the thin film has excellent performance as a diffusion barrier, a dielectric film, or an insulating film and may reduce corrosion of metal wiring materials, but the present invention is not limited thereto.

For example, the thin film may have a thickness of 1 to 30 nm, preferably 2 to 27 nm, more preferably 3 to 25 nm, still more preferably 5 to 23 nm. Within this range, thin film properties may be excellent.

For example, the thin film may have a resistivity value of 5 to 2,000 μΩ·cm, preferably 5 to 1,900 μΩ·cm based on a thin film thickness of 10 nm. Within this range, thin film properties may be excellent.

The thin film may have a halogen content of preferably 10,000 ppm or less or 0.001 to 8,000 ppm, still more preferably 0.001 to 5,000 ppm, still more preferably 0.001 to 1,000 ppm as measured by X-ray photoelectron spectroscopy (XPS). Within this range, thin film properties may be excellent, and corrosion of metal wiring materials may be reduced. Here, for example, halogens remaining in the thin film may include C12, Cl, and Cl⁻. As the amount of halogens remaining in the thin film decreases, film quality may be increased.

In addition, when residual halogen intensity (c/s) in a thin film having a thickness of 100 Å (10 nm) is measured according to secondary ion mass spectrometry (SIMS), the thin film may have a residual halogen intensity (c/s) of preferably 100,000 or less, more preferably 90,000 or less, still more preferably 80,000 or less, still more preferably 76,000 or less. Within this range, the effect of preventing corrosion and deterioration may be excellent. Here, for example, halogens remaining in the thin film may include F₂, F, and F⁻. As the amount of halogens remaining in the thin film decreases, film quality may be increased.

For example, the thin film may have a step coverage of 80% or more, preferably 90% or more, more preferably 95% or more. Within this range, even a thin film having a complex structure may be easily deposited on a substrate. Thus, the thin film may be applied to next-generation semiconductor devices.

As a specific example, the formed thin film may include one or more selected from the group consisting of a molybdenum thin film, a molybdenum nitride film (MoₓN_{y}, 0<x≤1.2, 0<y≤1.2, preferably 0.83x≤1, 0.83y≤1, more preferably x and y being 1) and a molybdenum oxide film (MozO_{w}, 0<x≤1.2, 0<y≤1.2, preferably 0.83x≤1, 0.8≤y≤1, more preferably x and y being 1), preferably a molybdenum nitride film. In this case, the thin film may be usefully used as a diffusion barrier, an etch stop film, or an electrode for semiconductor devices.

Other metal thin films, metal nitride films, and metal oxide films presented in the present invention may also be applicable. For example, when using an oxidizing agent such as oxygen and ozone as the reaction gas, a thin film represented by Chemical Formula 61 may be formed.

(M1-aM″a) Ob [Chemical Formula 61]

In Chemical Formula 61, a satisfies the inequality of 0≤a<1; b satisfies the inequality of 0<b≥2; and M is an atom belonging to the group 4 or is selected from titanium (Ti), zirconium (Zr), hafnium (Hf), silicon (Si), germanium (Ge), tin (Sn), strontium (Sr), niobium (Nb), barium (Ba), or tantalum (Ta).

For example, when necessary, the thin film may have a multilayer structure consisting of two or three layers. As a specific example, the multilayer structure consisting of two layers may be a lower layer-middle layer structure, and the multilayer structure consisting of three layers may be a lower layer-middle layer-upper layer structure.

The lower layer may be a dielectric film. For example, the lower layer may be composed of one or more selected from the group consisting of SiO₂, MgO, Al₂O₃, CaO, ZrSiO₄, ZrO₂, HfSiO₄, Y₂O₃, HfO₂, LaLuO₂, LaAlO₃, BaZrO₃, SrZrO₃, SrTiO₃, BaTiO₃, Si₃N₄, SrO, La₂O₃, Ta₂O₅, BaO, and TiO₂.

For example, the middle layer may be composed of TiₓN_{y}, preferably TiN.

For example, the upper layer may be composed of one or more selected from the group consisting of W and Mo.

Hereinafter, the present invention will be described in more detail with reference to the following preferred examples and drawings. However, these examples and drawings are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

### Examples 1 to 5, Comparative Examples 1 to 3, and Reference Examples 1 and 2

The combinations shown in Table 1 below were selected as the growth regulators and the metal thin film precursor compounds used in Examples 1 to 5, Comparative Examples 1 to 3, and Reference Examples 1 and 2.

TABLE 1

| Metal thin film precursor | |
|---|---|
| compound | Growth regulator |
| MoO₂Cl₂ | Tert-butyl iodide |
| MoO₂Cl₂ | Diiodomethane |
| MoO₂Cl₂ | 1-Iodobutane |
| MoO₂Cl₂ | 2-Iodobutane |
| MoO₂Cl₂ | Cyclohexyl iodide |
| MoO₂Cl₂ | 2-Iodo-2-methyl propane |
| MoO₂Cl₂ | 1-Bromo-1-methyl cyclohexane |
| MoO₂Cl₂ | 3-Iodo-2,4-dimethylpentane |
| MoO₂Cl₂ | Aniline |
| MoO₂Cl₂ | N-methylaniline |
| MoO₂Cl₂ | N,N-Dimethylaniline |
| MoO₂Cl₂ | Acetonitrile |
| MoO₂Cl₂ | Diethylether |
| MoO₂Cl₂ | Anisole |
| MoO₂Cl₂ | Dimethylsulfide |
| MoO₂Cl₂ | 3-Ethyl-2-pentene |
| MoO₂Cl₂ | 1,2,3-Trichloropropane |

### Examples 1 to 3

Among the compounds shown in Table 1, tert-butyl iodide was prepared as the growth regulator, and MoO₂Cl₂ was prepared as the metal thin film precursor compound. The prepared growth regulator and thin film precursor compound were placed in a canister and supplied to a vaporizer heated to 150° C. at a flow rate of 0.05 g/min using a liquid mass flow controller (LMFC) at room temperature.

The growth regulator and thin film precursor compound vaporized in the vaporizer were fed into a deposition chamber loaded with a substrate for 1 second at a feeding amount ratio of 1:1, and then argon gas was supplied thereto at 5,000 sccm for 2 seconds to perform argon purging. At this time, the pressure in the reaction chamber was controlled to 2.5 Torr.

Next, after introducing ammonia as a reactive gas into the reaction chamber at 1,000 sccm for 3 seconds, argon purging was performed for 3 seconds. At this time, the substrate on which a metal thin film is to be formed was heated to the temperature shown in Table 2 below. This process was repeated 200 to 400 times to form a MoN thin film having a thickness of 10 nm as a self-limiting atomic layer.

### Comparative Examples 1 to 3

The same process as in Examples 1 to 3 was performed except that the growth regulator is not included.

As a result, a 10 nm thick MoN thin film, which is a self-limiting atomic layer, was formed.

### Example 4

The same process as in Example 1 was performed except that a growth regulator and thin film precursor compound vaporized in a vaporizer were sequentially injected into a deposition chamber loaded with a substrate at a feeding amount ratio of 1:1 for 1 second, argon gas was supplied into the chamber at 5,000 sccm for 2 seconds, and argon purging was performed.

Specifically, a growth regulator vaporized in a vaporizer was injected into a deposition chamber loaded with a substrate for 1 second, argon gas was supplied into the chamber at 5,000 sccm for 2 seconds, and argon purging was performed. Next, a metal 1 thin film precursor compound vaporized in a vaporizer was injected into the deposition chamber loaded with a substrate for 1 second, argon gas was supplied into the chamber at 5,000 sccm for 2 seconds, and argon purging was performed.

The process was repeated 200 to 400 times to form a 10 nm thick MoN thin film, which is a self-limiting atomic layer.

### Example 5

The same process as in Example 1 was performed except that a growth regulator and thin film precursor compound vaporized in a vaporizer were sequentially injected into a deposition chamber loaded with a substrate at a feeding amount ratio of 1:1 for 1 second, argon gas was supplied into the chamber at 5,000 sccm for 2 seconds, and argon purging was performed.

Specifically, a metal thin film precursor compound vaporized in a vaporizer was injected into a deposition chamber loaded with a substrate for 1 second, argon gas was supplied into the chamber at 5,000 sccm for 2 seconds, and argon purging was performed. Next, a growth regulator vaporized in a vaporizer was injected into the deposition chamber loaded with a substrate for 1 second, argon gas was supplied into the chamber at 5,000 sccm for 2 seconds, and argon purging was performed.

The process was repeated 200 to 400 times to form a 10 nm thick MoN thin film, which is a self-limiting atomic layer.

### Reference Example 1

The same process as in Example 1 was performed except that, as the growth regulator, 3-iodo butane was used instead of tert-butyl iodide.

As a result, a 10 nm thick MoN thin film, which is a self-limiting atomic layer, was formed.

### Test Examples

### 1) Deposition Evaluation (Deposition Rate per Cycle, GPC)

An ellipsometer capable of measuring the optical properties of a thin film including thickness and refractive index using the polarization characteristics of light was used to measure the thickness of the formed thin film. The thickness of the thin film deposited per one cycle was calculated by dividing the measured thickness value by the number of cycles. Based on the calculated values, deposition rate was evaluated, and the results are shown in Table 2 below.

### 2) Evaluation of Thin Film Resistance (Resistivity)

The surface resistance of the formed thin film was measured using the four-point probe method, and the resistivity value thereof was calculated based on the thickness value of the thin film.

The degree of improvement in resistivity (μΩ·cm) was calculated according to Equation 1 below.

Degree of improvement in resistivity (8)=[(Resistivity when precursor composition is used−resistivity when no growth regulator is used)/Resistivity when no growth regulator is used]×100 [Equation 1]

TABLE 2

| | Growth | | GPC | Resistivity |
|---|---|---|---|---|
| | regulator | Deposition | deposition | (μΩ · cm) |
| | (Injection | temperature | rate | (*Control |
| Classification | method) | (° C.) | (Å/cycle) | group) |
| Example 1 | Tert-butyl | 380 | 0.952 | 1884 |
| | iodide (Mixing | | | |
| | injection) | | | |
| Example 2 | Tert-butyl | 400 | 0.946 | 1280 |
| | iodide (Mixing | | | |
| | injection) | | | |
| Example 3 | Tert-butyl | 420 | 1.156 | 919 |
| | iodide (Mixing | | | |
| | injection) | | | |
| Comparative | — (Mixing | 380 | 0.566 | 2350 |
| Example 1 | injection) | | | |
| Comparative | — (Mixing | 400 | 0.704 | 2300 |
| Example 2 | injection) | | | |
| Comparative | — (Mixing | 420 | 0.781 | 1697 |
| Example 3 | injection) | | | |

As shown in Table 2, the case (Examples 1 to 3) of using tert-butyl iodide as the growth regulator of the present invention in combination with the thin film precursor compound exhibited deposition rates equivalent or similar to those of the case (Comparative Examples 1 to 3) in which no growth regulator is used. In addition, in the case of Examples 1 to 3, resistivity was reduced to a range of 919 to 1,884 μΩ·cm. These results indicated that, in Examples 1 to 3, thin film growth rate was appropriately controlled and electrical properties were improved.

### 3) Impurities Reduction Characteristics

To compare the characteristics of reducing impurities (i.e., process by-products) in the formed thin film having a thickness of 10 nm, X-ray photoelectron spectroscopy (XPS) was performed on titanium (Ti), nitrogen (N), chlorine (Cl), carbon (C), and oxygen (O), and the results are shown in Table 3 below.

TABLE 3

| | Growth | Impurities (%) | | | | |
|---|---|---|---|---|---|---|
| Classification | regulator | Ti | N | Cl | C | O |
| Comparative | X | 38.07 | 38.01 | 0.10 | 0.11 | 23.71 |
| Example 1 | | | | | | |
| Example 1 | Tert-butyl | 37.21 | 33.18 | 1.02 | 0.51 | 28.08 |
| | iodide | | | | | |
| Reference | 3-Iodopentane | 39.18 | 39.18 | 0.05 | 0.01 | 21.63 |
| Example 1 | | | | | | |

As shown in Table 3, the impurity content of the case (Example 1) of using the growth regulator of the present invention and the thin film precursor compound at the same time was the same as or similar to that of the case (Comparative Example 1) in which no growth regulator was used. In addition, compared to the case (Reference Example 1) of using another growth regulator, the intensities of Cl and C were reduced to about 0.01%. These results indicated that Example 1 had excellent impurities reduction characteristics.

In particular, in the case of Comparative Example 1, since the growth regulator was not added, carbon should not be detected in theory. However, carbon, which was presumed to originate from trace amounts of CO and/or CO₂ contained in the thin film precursor compound, the purge gas, and the reaction gas, was detected. In Example 1 of the present invention, even though a hydrocarbon compound as the growth regulator was added during thin film deposition, the carbon intensity was reduced compared to Comparative Example 1. These results indicated that the growth regulator of the present invention had excellent impurities reduction characteristics.

In particular, in Reference Example 1, although a compound having a halide-based structure similar to the growth regulator of the present invention was added, the intensity of impurities was too high compared to Example 1 and Comparative Example 1. These results indicated that the compound of Reference Example 1 had no effect in improving film quality.

In addition, to confirm the effect of the growth regulator depending on the injection step thereof, the following experiments were additionally conducted.

### Additional Example 1

ALD deposition evaluation was performed using MoO₂Cl₂ as the Mo precursor according to a VFC supply method.

The canister heating temperature of MoO₂Cl₂ was 90° C., and deposition temperature was 380° C., 400° C., or 420° C. Process pressure was 6 torr, and the flow rate of each of ammonia reaction gas and Ar purge gas was 1,000 sccm.

To confirm the effect of improving resistivity and GPC, MoN thin films were deposited and compared.

Specifically, an ALD deposition experiment (post-injection) was performed by injecting MoO₂Cl₂, performing Ar purging, injecting tert-butyl iodide, injecting Ar, injecting an NH₃ reaction gas, and then injecting Ar, and an ALD deposition experiment (pre-injection) was performed by injecting tert-butyl iodide, injecting Ar, injecting MoO₂Cl₂, injecting Ar, injecting an NH₃ reaction gas, and injecting Ar. According to the methods described in the experimental example, resistivity and deposition rate were measured. As a control, the resistivity and deposition rate of the MoN thin film formed without the growth regulator were measured according to the same manners.

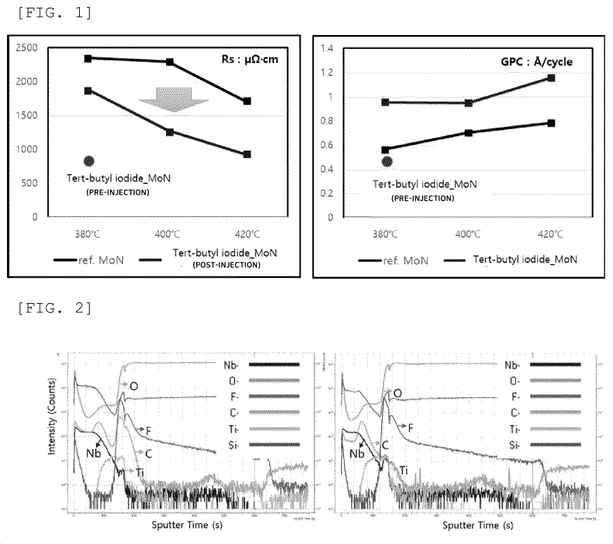

The measurement results are shown in FIG. 1 below.

FIG. 1 is a diagram comparing an experiment in which MoO₂Cl₂ was injected first and the growth regulator of the present invention was injected later and a control experiment in which no growth regulator was used.

As shown in FIG. 1, compared to the control group, resistivity was reduced by 35%, and deposition rate was increased by 34%.

Although specific measurement results were not attached, resistivity was further improved in the case of pre-injection of tert-butyl iodide as the growth regulator, compared to the post-injection of tert-butyl iodide.

### Additional Example 2

The same process as in Additional Example 1 was performed except that NbFs was used instead of MoO₂Cl₂ to form an NbN thin film.

The measurement results are shown in Table 4 and FIG. 2 below.

Table 4 and FIG. 2 show the results of comparing an experiment in which the growth regulator of the present invention was injected first and NbFs was injected later and a control experiment in which no growth regulator was used.

As shown in Table 4 and FIG. 2, compared to the NbN thin film of the control group, F and C impurities were improved based on the SIMS analysis results.

TABLE 4

| Classification | Control group | NbN (pre-injection) |
|---|---|---|
| F intensity (c/s) | 116.925 | 75.197 |
| C intensity (c/s) | 1,466 | 656 |

1. A metal thin film precursor composition, comprising a thin film precursor compound; and a growth regulator,
wherein the thin film precursor compound comprises a compound represented by Chemical Formula 1 below, and the growth regulator is a straight-chain, branched, cyclic, or aromatic compound represented by Chemical Formula 2 below.
MₓNₙLₘ, [Chemical Formula 1]
wherein x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, TI, Pb, Bi, Pt, At, and Tn; n is an integer from 0 to 8; N is F, Cl, Br, or I or a ligand consisting of a combination of two or more selected from the group consisting of F, Cl, Br, and I; m is an integer from 0 to 5; and L is H, C, N, O, P, or S or a ligand consisting of a combination of two or more selected from the group consisting of H, C, N, O, and P.
AnBmXoYiZj, [Chemical Formula 2]
wherein A is carbon, silicon, nitrogen, phosphorus, or sulfur; B is hydrogen, an alkyl having 1 to 10 carbon atoms, a cycloalkyl having 3 to 10 carbon atoms, or an alkoxy having 1 to 10 carbon atoms; X comprises one or more of fluorine (F), chlorine (Cl), bromine (Br), and iodine (I); Y and Z independently comprise one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.

2. The metal thin film precursor composition according to claim 1, wherein, in Chemical Formula 1, n is an integer from 1 to 6.

3. The metal thin film precursor composition according to claim 1, wherein, in Chemical Formula 1, N is F, Cl, or Br or a ligand consisting of a combination of two or more selected from the group consisting of F, Cl, and Br.

4. The metal thin film precursor composition according to claim 1, wherein the growth regulator is Cl, Br, or I or has a halide terminal group consisting of a combination of two or more selected from the group consisting of Cl, Br, and I.

5. The metal thin film precursor composition according to claim 1, comprising one or more selected from compounds represented by Chemical Formulas 40 to 60 below. 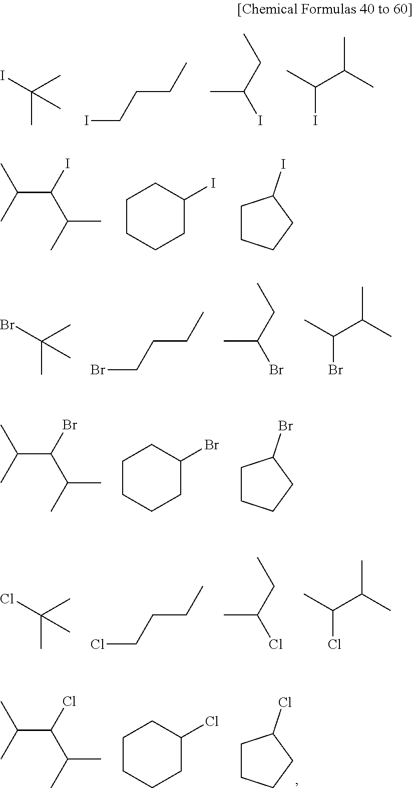
wherein, in Chemical Formulas 40 to 60, a line is a bond; carbon is located at a point where bonds meet without indicating a separate element; and the number of hydrogen atoms satisfying a valence of the carbon is omitted.

6. The metal thin film precursor composition according to claim 1, wherein the metal thin film precursor composition is used in an atomic layer deposition (ALD) process, a plasma atomic layer deposition (PEALD) process, a chemical vapor deposition (CVD) process, or a plasma chemical vapor deposition (PECVD) process.

7. A method of forming a thin film, comprising injecting the metal thin film precursor composition according to claim 1 into a chamber and adsorbing the metal thin film precursor composition on a surface of a loaded substrate.

8. The method according to claim 7, comprising:
i) vaporizing a growth regulator and adsorbing the growth regulator on a surface of a substrate loaded in a chamber;
ii) performing first purging of an inside of the chamber using a purge gas;
iii) vaporizing a thin film precursor compound in the chamber and adsorbing the thin film precursor compound on a surface area different from the surface area of the substrate on which the growth regulator is adsorbed or bonding the thin film precursor compound to a terminal of the growth regulator adsorbed on the substrate;
iv) performing second purging of the inside of the chamber using a purge gas;
v) supplying a reaction gas into the chamber; and
vi) performing third purging of the inside of the chamber using a purge gas.

9. The method according to claim 7, comprising:
i-1) vaporizing a thin film precursor compound and adsorbing the thin film precursor compound on a surface area of the substrate loaded in the chamber, wherein the surface area is different from the surface area of the substrate on which the growth regulator is adsorbed, or bonding the thin film precursor compound to a terminal of the growth regulator adsorbed on the substrate;
ii) performing first purging of an inside of the chamber using a purge gas;
v) supplying a reaction gas into the chamber; and
vi-1) performing additional purging of the inside of the chamber using a purge gas.

10. The method according to claim 7, comprising:
i-2) vaporizing a thin film precursor compound and adsorbing the thin film precursor compound on a surface of a substrate loaded in a chamber;
ii) performing first purging of an inside of the chamber using a purge gas;
iii) vaporizing a growth regulator in the chamber and adsorbing the growth regulator on a surface area different from the surface area of the substrate on which the thin film precursor compound is adsorbed or bonding the growth regulator to a terminal of the thin film precursor compound adsorbed on the substrate;
iv) performing second purging of the inside of the chamber using a purge gas;
v) supplying a reaction gas into the chamber; and
vi) performing third purging of the inside of the chamber using a purge gas.

11. The method according to claim 7, wherein the metal thin film precursor composition is transferred into an ALD chamber, a CVD chamber, a PEALD chamber, or a PECVD chamber by a VFC method, a DLI method, or an LDS method.

12. The method according to claim 7, wherein the reaction gas is a reducing agent, a nitrifying agent, or an oxidizing agent.

13. The method according to claim 7, wherein deposition temperature is 50 to 700° C.

14. The method according to claim 7, wherein the thin film is an oxide film, a nitride film, or a metal film.

15. The method according to claim 7, wherein the thin film comprises a multilayer structure consisting of two or three layers.

16. A semiconductor substrate fabricated using the method according to claim 7.
